(19) United States
(12) Patent Application Publication
(10) Pub. No.: US 2007/0297136 A1
(43) Pub. Date: Dec. 27, 2007

(54) MODULAR LIQUID COOLING OF ELECTRONIC COMPONENTS WHILE PRESERVING DATA CENTER INTEGRITY

(75) Inventor: Michael V. Konshak, Louisville, CO (US)

Correspondence Address: HOGAN & HARTSON LLP, ONE TABOR CENTER, SUITE 1500, 1200 SEVENTEEN ST., DENVER, CO, 80202, US

(73) Assignee: SUN MICOSYSTEMS, INC., Santa Clara, CA (US)

(21) Appl. No.: 11/426,238

(22) Filed: Jun. 23, 2006

(51) Int. Cl. H05K 7/20

(52) U.S. Cl. 361/699

(57) ABSTRACT

The integrity of the data center cooling system is maintained by using separate and independent cooling loops to collect heat from electronic components housed in modular units. According to one embodiment of the present invention, a first cooling loop is associated with each modular unit. The first cooling loop comprises a coolant that accepts heat from electronic components housed within the modular unit and transports the heat to a heat exchanging system. The heat exchanging system conducts heat from the coolant of the first loop to coolant associated with the data center cooling system. Coolant from the data center cooling system accepts heat from the coolant associated with the first loop and conveys it away from the data center.

### BACKGROUND OF THE INVENTION

1. Field of the Invention

This invention relates generally to electronic assemblies, and, more particularly, to thermal management of electronic assemblies using liquid cooling systems.

2. Relevant Background

Electronic devices generate heat during operation. Thermal management refers to the ability to keep temperature-sensitive elements in an electronic device within a prescribed operating temperature. As one might expect, thermal management has evolved to address the increased heat generation created within electronic devices as a result of increased processing speed/power of the electronic devices.

Historically, electronic devices were cooled by a natural radiation thermal management technique. The cases or packaging of these prior art electronic devices were designed with openings (e.g., slots) strategically located to allow warm air to escape and cooler air to be drawn in. As heat generation increased, fans were added to increase the volume of cooling air circulating around the heat generating electronics.

The processing speeds of computer systems have recently climbed from 25 MHZ to more than 1400 MHZ. As performance climbs so too does heat production. The advent of such high performance processors and electronic devices now requires more innovative thermal management. Each of these increases in processing speed and power generally carries a cost of increased heat generation such that natural radiation is no longer sufficient to provide proper thermal management.

Several methods have been employed for cooling high performance electronic devices. One common method of cooling these types of devices is by attaching heat sinks. The heat sinks are typically used in combination with a fan that forces air to pass by the heat sinks and/or devices.

There are several problems with cooling systems that utilize some form of a heat sink and fan combination. One problem is that the fan must typically be located close to the fins of the heat sink to generate fully developed air flow. When a large fan is used in conjunction with a heat sink to cool an electronic component, a large percentage of the air moved by the system fan does not go through the heat sink. As a result, even large fans are not an efficient thermal solution for cooling some electronic devices.

Some of the new high performance cooling systems are utilizing multiple fans to maintain proper operating temperatures. However, the additional fans in multiple fan cooling systems adds unwanted expense to manufacturing such electronic devices. In addition, the additional fans are noisy, bulky and utilize an inordinate amount of space within the environment where the electronic device is located. A more significant limitation of this type of cooling is that air cooling relies on the ability to maintain a cool operating environment. As the heat being produced from each component rises and the density of the components increase, the amount of heat dissipated into the surrounding environment by the traditional air cooled means may exceed the capability of the environmental control system. Put simply, it becomes economically infeasible to keep a room at a consistent temperature that will facilitate air cooling.

An alternative and more costly system to manage the thermal energy output of high-powered processors is a single-phase, single loop pumped liquid cooling system. The system uses a heat exchanger that is thermally connected to the electronic device. The heat exchanger draws thermal energy from the device and heats up a liquid coolant which is passed through the heat exchanger. A pump transfers the liquid coolant through a second heat exchanger that draws the thermal energy from the liquid coolant. The liquid coolant leaves the second heat exchanger at a low enough temperature to cool the processor once the coolant cycles back to the first heat exchanger.

These single-phase cooling systems suffer from several drawbacks. One drawback is that the systems are inefficient. Another drawback is that the systems require the use of a pump. These pumps require maintenance and commonly break down or leak onto one or more of the electrical components. Replacement, addition, or modification to the heat exchangers requires the integrity of the cooling loop to be compromised. Often the risk of rendering an entire system inoperative due to maintenance on a single cooling component is formidable.

The most recent trend has seen the use of two-phase, single loop cooling systems to cool high-powered processors. These two phase cooling systems include an evaporator that removes thermal energy from the processor. The thermal energy causes a coolant within the evaporator to turn from a liquid into a vapor (i.e. to evaporate).

The coolant is typically transferred through an expansion valve before the coolant enters the evaporator. The expansion valve reduces the pressure of the coolant and also reduces the temperature to enhance the efficiency of the cooling system and allow for coolant temperatures that are different from what otherwise would normally be available.

The coolant also typically exits the evaporator into a compressor, or pump, that transports the coolant from the evaporator into a condenser. The coolant leaves the pump at a higher pressure and temperature such that as the coolant flows through the condenser, energy can be easily removed from the coolant to the local air causing any vaporized coolant to readily condense back to a liquid. Once the coolant is in liquid form, it can be transported back to the evaporator after passing through the expansion valve.

These two-phase cooling systems also require the use of a pump such that they suffer from many of the drawbacks of single-phase systems. If these types of cooling systems are operated without using a pump, there could be problems depending on the orientation of the cooling system. In some orientations, gravity forces the liquid coolant away from the evaporator making it impossible for the evaporator to cool the processor through evaporation of the coolant.

Another solution to the thermal management problem is an internal liquid cooling system. In such a system the electronic components are placed on a cold plate through which a working fluid, such as a refrigerant or other coolant, is passed. Heat is rejected from the electronic components into the working fluid passing through the cold plate. Typically, the emerging working fluid is then run through an air-cooled heat exchanger where the heat is rejected from the working fluid to an air-stream that takes the heat away from the system. While such systems may work well for their intended purpose, it normally results in a raising of the ambient temperature of the environment in which the electronic devices are housed. As the size of processors continues to decrease and the thermal production capacity continues to increase, even this form of thermal management becomes untenable. While heat is removed effectively from the individual components, it is not adequately disposed of from the surrounding environment resulting in a raised ambient temperature and as the ambient temperature rises and the temperature gradient between the heat exchanger diminishes, thus the effectiveness of the cooling system is reduced.

What is needed is a modular liquid cooling system that maintains the integrity of a facility cooling system yet provides the means by which to change, add, remove and maintain modular units within the facility. These module systems also need an effective liquid cooling system, separate from the facility cooling system to efficiently and effectively convey heat away from the heat producing components and to the cooling medium. Finally, what is needed is a means to convey heat from the first modular cooling system to the second facility cooling system that is thermally conductive and efficient while maintaining the mobility and flexibility of the modular design allowing for quick removal and replacement of the modular components.

### SUMMARY OF THE INVENTION

Briefly stated, the present invention involves liquid cooling of modular components in a data center while preserving the integrity of a data center cooling system. The integrity of the data center cooling system is maintained by using a separate and independent cooling loop to collect heat from electronic components housed in modular units. According to one embodiment of the present invention, a first cooling loop is associated with each modular unit. The first cooling loop comprises a coolant that accepts heat from electronic components housed within the modular unit and transports the heat to a conductive element. The portion of the conductive element associated with the modular unit accepts the heat from the first cooling loop and transfers it to a second portion of the conductive element that is associated with the data center cooling system. Coolant from the data center cooling system accepts heat from the second portion of the conductive element and conveys it away from the data center.

In another embodiment of the present invention, each modular unit connects to a first cooling loop associated with a rack in the data center. Each modular unit possesses channels to thermally interface with the electronic components housed in the modular unit so as to convey coolant associated with the rack cooling loop to the electronic components. The channels in each modular unit are coupled to the rack cooling loop via quick connect/disconnect fittings. Coolant from the rack cooling system is circulated to each modular unit mounted in the rack so as to collect heat and then transported to a heat exchanger where it interfaces with the data center cooling systems. The heat exchanger facilitates the conduction of heat from the coolant associated with the rack cooling system to the coolant associated with the data center cooling system.

The foregoing and other features, utilities and advantages of the invention will be apparent from the following more particular description of an embodiment of the invention as illustrated in the accompanying drawings.

### BRIEF DESCRIPTION OF THE DRAWINGS

The aforementioned and other features and objects of the present invention and the manner of attaining them will become more apparent and the invention itself will be best understood by reference to the following description of a preferred embodiment taken in conjunction with the accompanying drawings, wherein:

FIG. 1 shows a typical configuration of racks in a data center according to one embodiment of the present invention;

FIG. 2 shows a high level block diagram for modular cooling of electronic components while preserving the integrity of a data center cooling structure according to one embodiment of the present invention;

FIG. 3 shows a system for modular cooling of electronic components while preserving the integrity of a data center cooling structure according to one embodiment of the present invention;

FIGS. 4a and 4b show a perspective view of one embodiment of a modular component and conductive element for use in a system for modular cooling of electronic components according to the present invention;

FIG. 5 shows a side view of one embodiment of a conductive element for use in a system for modular cooling of electronic components according to the present invention;

FIGS. 6a and 6b comprise two side views of the conductive element of FIG. 5 showing the operation of a tightening device to increase surface contact and thermal transfer between opposing portions of the conductive element according to one embodiment of the present invention;

FIG. 7 is a high level block diagram of an alternate embodiment for modular cooling of electronic components while preserving the integrity of a data center cooling system according to the present invention;

FIG. 8 shows another schematic of the alternate embodiment of FIG. 7 for modular cooling of electronic components while preserving the integrity of a data center cooling structure according to the present invention;

FIG. 9 shows a perspective view of a rack for housing modular components using a system for cooling of electronic components while preserving the integrity of a data center cooling structure according to one embodiment of the present invention; and

FIG. 10 is a flow diagram for a method for modular cooling of electronic components while preserving the integrity of a data center cooling structure according to one embodiment of the present invention.

The Figures depict embodiments of the present invention for purposes of illustration only. One skilled in the art will readily recognize from the following discussion that alternative embodiments of the structures and methods illustrated herein may be employed without departing from the principles of the invention described herein.

### DETAILED DESCRIPTION OF THE PREFERRED EMBODIMENTS

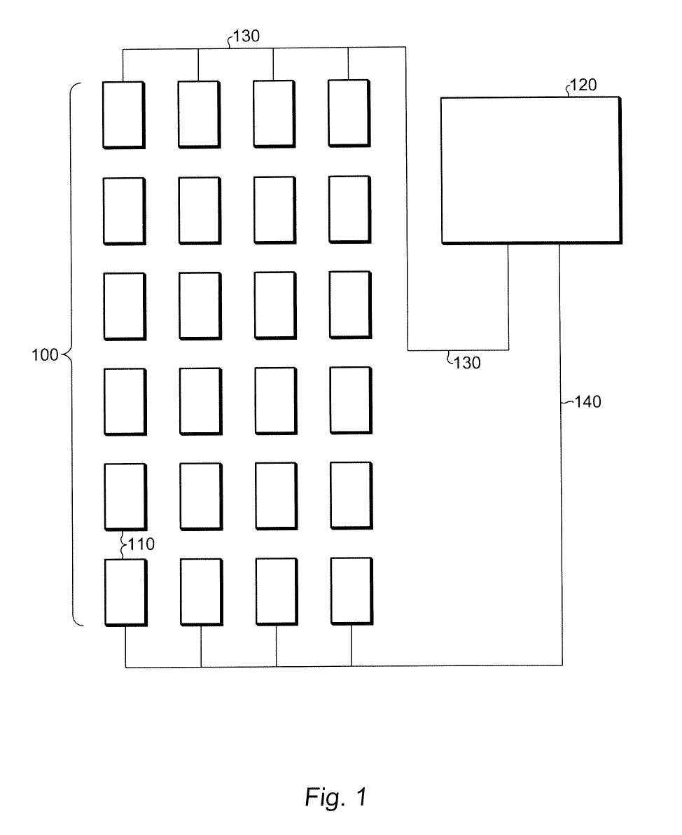

The present invention is illustrated and described in terms of the aforementioned figures. A data center houses a multitude of electronic components and devices such as servers, data storage devices, tape drives, communication switches, and other electronic components in a single location. By consolidating the location of these electronic components, security, fire suppressant, as well as environmental considerations can be economized. FIG. 1 shows a typical data center 100 according to one embodiment of the present invention. As previously described, the density of electronic components and the heat that these components produce has risen to the point of requiring new and innovative means to control the environment in which they operate.

The data center 100 of FIG. 1 shows multiple racks 110 or cabinets in which the electronic components are maintained. In each rack 110, multiple modular components, designed so as to be easily removed and replaced, are housed. The racks 110, however, are typically semi-permanent components of the data center 100. According to the present invention, each rack is coupled to a cooling structure that centrally provides a liquid cooling resource 120 to each rack 110. In the embodiment shown in FIG. 1, a cooling resource 120 is shown as a separate entity from the data center 100 housing the racks 110 of electronic components. The cooling resource 120 is functionally connected to each rack 110 in the data center 100 to provide each rack 110 with a cooling means. As shown in FIG. 1, a series of coolant lines 130 supplies each rack with a coolant or refrigerant. As the coolant accepts heat from each of the racks 110 comprising the data center 100, the now warm coolant is returned to the cooling center 120 via separate return lines 140.

The cooling resource 120 acts to reject the heat acquired by the coolant so as to maintain the data center 100 environment. As will be appreciated by one skilled in the art, the cooling resource 120 may be any commercial cooling system or refrigeration type of system capable of taking large volumes of heated water or other types of coolant, extracting the heat from the liquid, and returning to the data center 100 a cool resource that can be used to cool electronic components. The cooling resource 120 is maintained separate from the data center 100 so as to extricate the heat from the data center 120 environment.

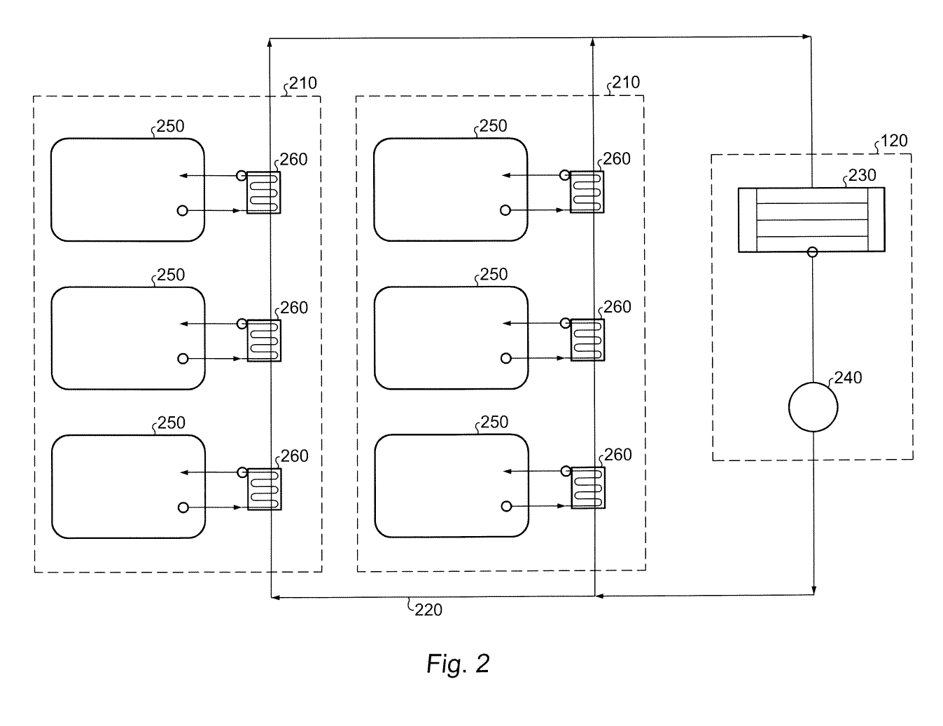

As previously described, electronic components are frequently removed and replaced. It is one object of the present invention to provide the means to remove and replace the various electronic components associated with a data center 100 without affecting the integrity of the data center's 100 cooling system. FIG. 2 shows a high level block diagram for modular cooling of electronic components while preserving the integrity of a data center cooling system according to one embodiment of the present invention. The cooling system of FIG. 2 shows two racks 210, each having multiple modular components 250. As shown in FIG. 2, each rack 210 is coupled to a cooling system comprising a cooling resource 120 and cooling feed and return lines 220.

The cooling resource 120 in FIG. 2 is shown to possess a condenser 230 for removing the heat from the liquid contained within the cooling feed and return line system 220 and a pump 240 to circulate the coolant. Components such as temperature sensors, pressure sensors, evaporators, and other elements known to one skilled in the relevant art are contemplated by the present invention. Furthermore, implementation methodologies for providing a liquid cooling resource are known within the art and the specifics of their application within the context of the present invention will be readily apparent to one of ordinary skill in the relevant art in light of this specification.

As shown in FIG. 2, the cooling resource 120 provides coolant to each of the racks 210. In one embodiment of the present invention, each rack possesses a heat exchanger 260 for each modular unit 250. In this example, each rack 120 possesses three modular units 250. Each unit is coupled to a heat exchanger 260 which is in fluid communication with the cooling line system 220.

In one embodiment of the present invention, each modular unit 250 possesses an internal liquid cooling system that is distinct from the data center cooling system. The modular cooling system channels coolant to the various electronic components within the modular unit so as to extract heat from each of the electronic components and deliver it to the heat exchanger 260 associated with the data center cooling system.

The modular cooling system can be contained within each module or can be part of a rack cooling system that is then thermally coupled to the data center 100 cooling system. When the modular cooling system is contained within each module it may employ an internal pump to circulate the coolant within the module or utilize heat pipes that rely on phase changes in the coolant to convey heat from the electronic components to the heat exchanger 260. Significantly, both approaches maintain the integrity of the primary data center 100 cooling system. The removal and/or replacement of modular units 250 in no way affects the integrity of the data center cooling system and thus does not jeopardize a data center 100 cooling system shut down that would render the entire data center inoperative.

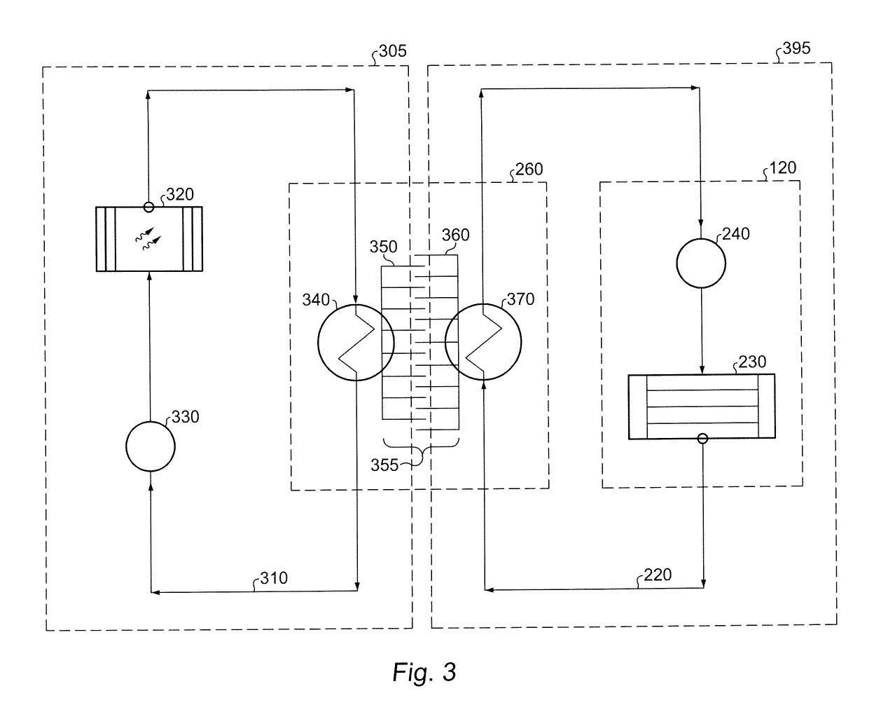

As mentioned, each modular unit 250 may possess an internal liquid cooling system or set of heat pipes designed to convey the heat, typically from the enclosed electronic components or heat sources, out of the modular unit 250 and ultimately external to the data center environment. FIG. 3 shows such a system for modular cooling of electronic components according to one embodiment of the present invention.

FIG. 3 shows two liquid cooling system loops. The first liquid cooling loop 305 refers to the cooling loop implemented to extract heat from the electronic components within the modular unit 250 and convey it to the heat exchanger 260. The liquid loop can be comprised of various types of liquid coolants or refrigerants as will be appreciated by one skilled in the art. Likewise various designs and their implementation of an internal liquid cooled system are contemplated by the present invention and each can be successfully utilized by the present invention. As with the data center cooling system, the implementation methodologies for providing liquid cooling to electronic components in a modular unit are known within the art and the specifics of their application within the context of the present invention will be readily apparent to one of ordinary skill in the relevant art in light of this specification.

In the embodiment shown in FIG. 3, the first cooling loop 305 possesses a means 320 by which the coolant is in thermal contact with the electronic components. A pump 330 circulates the coolant of the first cooling loop 305 via a cooling conduit 310 maintained within the modular unit 250. Also associated with the first cooling loop 305 is a heat exchanger 340 that provides a means to convey heat from the first cooling loop 305 to a second cooling loop 395 which, in this case, is synonymous to the data center 100 cooling system. The second cooling loop 395 receives heat via a heat exchange 370 that is in fluid and thermal communication with the second cooling loop's 395 cooling line system 220.

Interposed between the heat exchangers associated with the first cooling loop 305 and the second cooling loop 395 is a thermally conductive element 355. The conductive element 355 can provide support for mounting the modular unit 250 within the rack as well as conveying heat from the first heat exchanger 340 to the second heat exchanger 370. In other embodiments of the present invention the modular unit 250 is supported in the rack by a mounting fixture independent of the thermally conductive element 355. The conductive element, in one embodiment of the present invention, comprises a first portion 350 associated with the first cooling loop 305, and a second portion 360 associated with the second cooling loop 395. The first portion of the conductive element 350 accepts heat from the first cooling loop 305 heat exchanger and transfers that heat to the second portion of the conductive element 360. Correspondingly, the second portion of the conductive element 360 conveys the heat to the heat exchanger associated with the second cooling loop 395 which ultimately transfers the heat to the coolant within the loop and away from the data center.

In one embodiment of the present invention, the first and second portion of the conductive element 355 comprise interlocking surfaces. These surfaces can take of the form of fins, ridges, rails, and other shapes conducive to thermal conduction. As the two portions come together and into contact with each other, heat is transferred from the first portion of the conductive element 350 to the second portion of the conductive element 260 via conduction. Conduction is the process of energy transfer as heat through a stationary medium such as copper, water or air. In solids the energy transfer arises because atoms at the higher temperature vibrate more excitedly, hence they can transfer energy to more lackadaisical atoms nearby by microscopic work, that is, heat. In metals the free electrons also contribute to the heat-conduction process. In a liquid or gas the molecules are also mobile, and energy is also conducted by molecular collisions.

The other heat transfer mechanism is radiation which is the transfer of energy by disorganized photon propagation. The fact that radiation is disorganized makes radiation a very inefficient means to transfer heat. Convection is another term sometimes associated with heat transfer. Convection is the transfer of energy between moving fluids and solids. What is convected however is internal energy and not heat. A convective process may have some conductive heat transfer associated with it but convection is not the means of that transfer.

The heat transfer processes associated with the above described embodiment implements several instances of conduction. First, heat is conducted from the electronic components to the liquid in the first loop 310. Second, the heat in the first liquid is conducted to the first portion of the conductive element 350. Next, heat collected by the first portion of the conductive element 350 is conducted, and radiated, to the second portion of the conductive element 360. Thereafter heat gained by the second portion of the conductive element 360 is transferred via conduction to the liquid associated with the second cooling loop 395 and carried away from the data center 100 to the cooling center 120 where it is extracted from the second liquid.

Optimally, the joining of the first portion of the conductive element 350 and the second portion of the conductive element 360 creates a coupling that provides for maximal surface to surface contact so as to enhance conduction rather than rely on radiation as a means for heat transfer. The thermal interface between the first portion of the conductive element 350 and the second portion of the conductive element 360 can be enhanced by co-joining to each respective surface a thermally conductive interface material. The thermally conductive interface material improves thermal conducting by minimizing and ideally eliminating any voids or gaps between the respective portions. The minimization of voids, even at a microscopic level, significantly enhances the thermal conduction between conductive surfaces. The implementation methodologies of using such interface material is well known within the art and the specifics of their application within the context of the present invention will be readily apparent to one of ordinary skill in the relevant art in light of this specification.

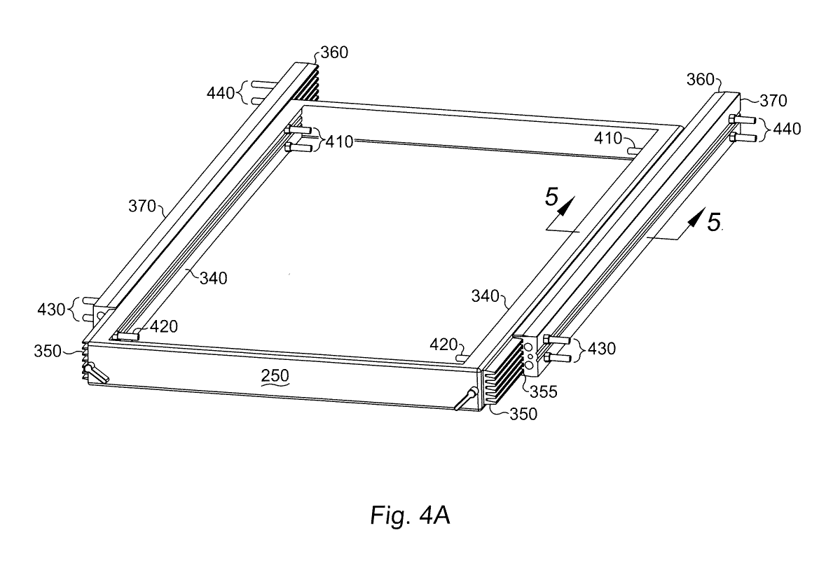

FIG. 4 shows a perspective view of one embodiment of a modular component and conductive element for use in a system for modular cooling of electronic components according to the present invention. The modular unit 250 shown in FIG. 4 can be used to house various electronic components (not shown). Within the modular unit a series of conduits and capillaries interface with, and are in thermal contact with, the electronic components so as to enable coolant within the first cooling loop to collect heat. The heated liquid enters a channel or conduit 415 in the first portion of the conductive element 350 via two inflow ports 410. The channel 415, as shown in subsequent figures, acts as a heat exchanger 340 to conduct heat from the liquid and to the first portion of the conductive element 350. The liquid exits the channel (heat exchanger) and reenters the area housing the electronic components via two similar exit ports 420 at the opposing end of the first portion 350. Similarly, the second portion of the conductive element 360 also has two channels 435 acting as a heat exchanger 370 possessing two input ports 430 and two exit ports 440.

As shown in FIG. 4, the conductive element 355 is a joining of opposing extensions or fins. The first portion of the conductive element 350 possesses a plurality of extensions along each longitudinal edge of the modular unit 250 creating a series of extensions and troughs. The second portion of the conductive element 360 is fixed to the rack and also possesses a plurality of extension and troughs opposing those of the first conductive element 350.

The modular unit 250 is supported by the extensions associated with the first portion of the conductive element 350 and the second portion of the conductive element 370. Accordingly, the extensions must be of sufficient strength to support the weight associated with the modular unit, the cooling system that is maintained within the modular unit, and the electronic components that reside in the modular unit 250. In this embodiment of the present invention, the extensions allow the modular unit 250 to slide into the rack facilitating both the mounting of the modular unit 250 and heat transfer simultaneously.

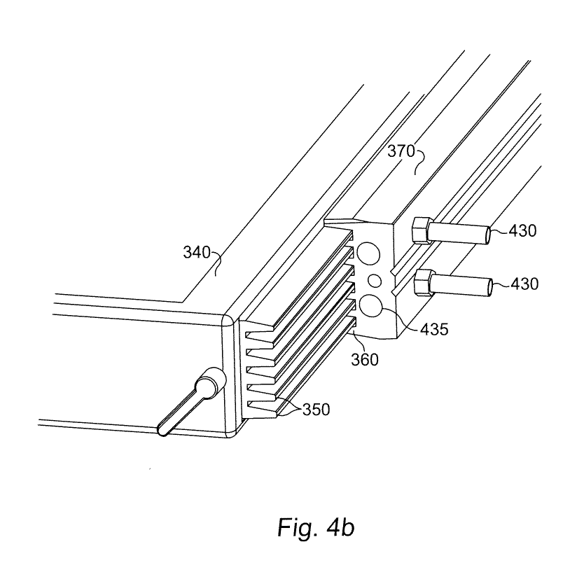

FIG. 5 shows a side view of one embodiment of a conductive element for use in a system for modular cooling of electronic components according to the present invention. Each extension 510 or surface associated with the first portion 350 shown in FIG. 5 is positioned to align with a trough of the second portion 360 and likewise the extension 520 of the second portion 360 is aligned with a trough of the first portion 360. The only exception to this configuration lies in the two bounding extensions 525 of the second portion. To fully capture and provide an optimal means for conductive heat transfer, each surface of the extensions from the first portion 350 are captured by a trough of the second portion 360. As a result, the number of extensions of the second portion 360 necessarily exceeds the number of extensions of the first portion 350 by at least one. (This feature can be fully seen in FIG. 5 as described below.) As shown in FIG. 5, the second portion of the conductive element 360 has seven extensions while the first portion of the conductive element 350 possesses six.

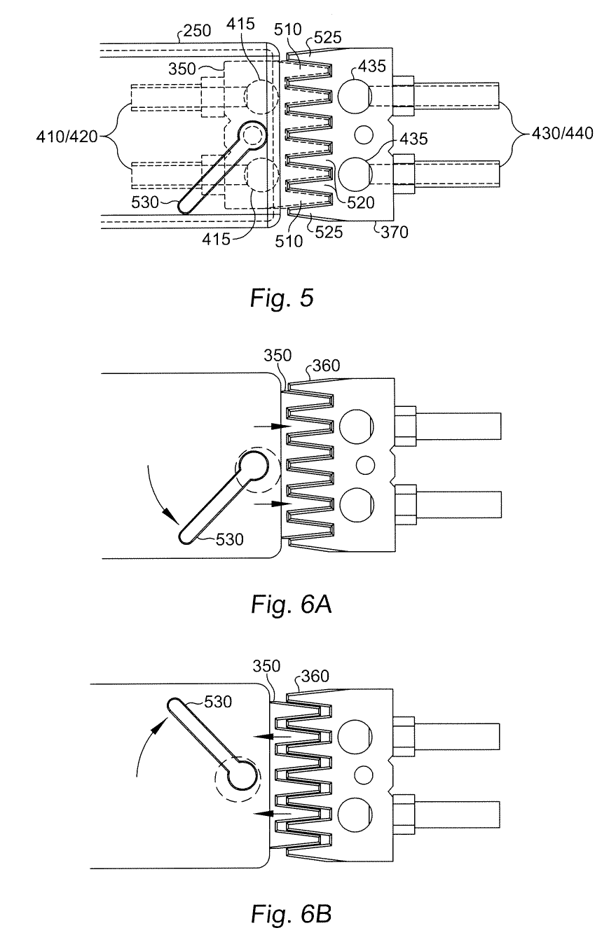

The shape of the extensions 510, 525 may vary as will be appreciated by one skilled in the art, provided a complimentary interface that maximizes surface area contact between the first and second portions of the conductive element is established. In the embodiment shown in FIG. 5, the extensions are trapezoidal in shape. Associated with the extensions, and shown in FIG. 5, is a tightening device 530 configured to drive the extensions associated with the first portion of the conductive element 350 into the troughs associated with the second portion of the conductive element 360 thus ensuring maximal surface contact between the two respective portions. FIG. 6 comprises two side views of the conductive element of FIG. 5 showing the operation of the tightening device 530 to increase surface contact and thermal transfer between opposing portions of the conductive element. In this embodiment of the present invention, the device 530 is associated with a cam that upon rotation drives the portions of the conductive element together. As the device 530 is rotated down, the cam places pressure on the first portion of the conductive element 350 forcing it into the stationary second portion of the conductive element 360. FIG. 6a shows the device in the closed, full contact position, and FIG. 6b shows the device in the open or retracted position revealing space between the extensions and the troughs of the respective portions of the conductive element to facilitate installation and removal of the modular unit 250.

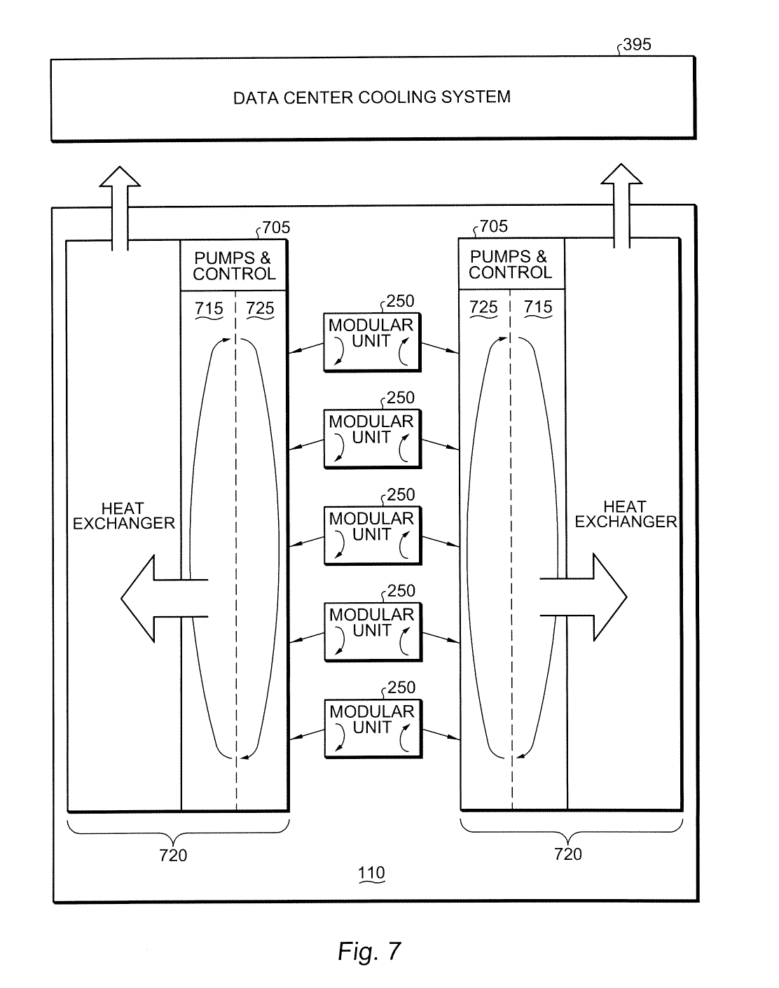

FIG. 7 is a high level block diagram of an alternate embodiment for modular cooling of electronic components while preserving the integrity of a data center cooling system according to the present invention. Depicted in FIG. 7 is a rack 110 that is thermally coupled to the data cooling center 100. Each rack 110 houses a plurality of modular units 250 that convey heat to one or more heat exchangers 720. The heat exchanger assemblies 720 are comprised of pumps and controls 705, manifolds 725, and radiators 715. Heat from each modular unit 250 is transferred from the modular unit cooling system to the data center cooling system 100 via the heat exchanger assembly 720 maintained within each rack 110.

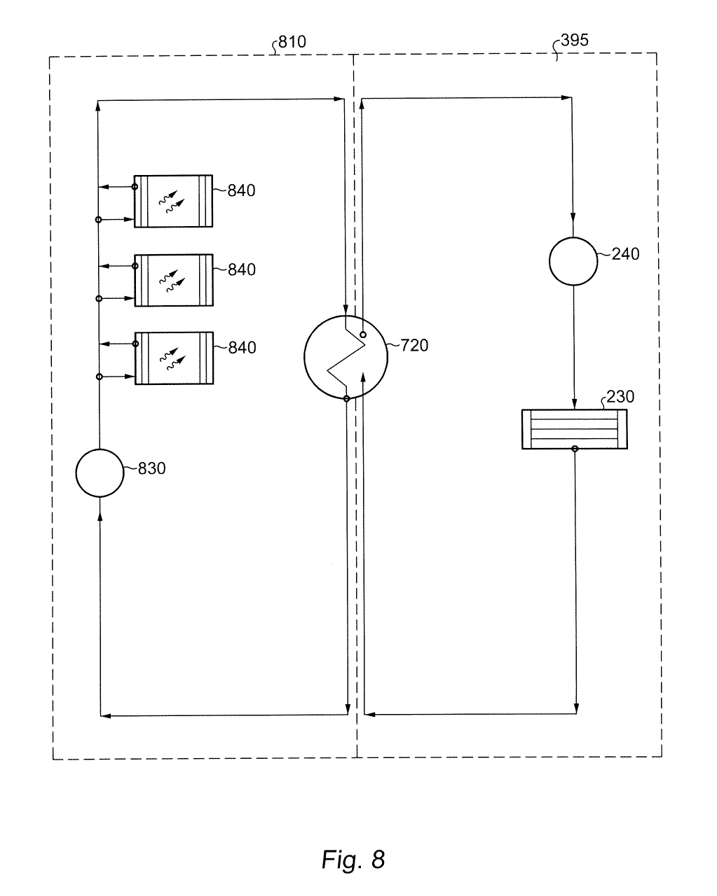

FIG. 8 shows a high level schematic of the alternate embodiment of FIG. 7 for modular cooling of electronic components according to the present invention. As described above, the system presented in FIGS. 7 and 8 shows an alternate means for transferring heat from the modular units 250 to the second cooling loop 395 that is associated with the data center 100 cooling system. According to this embodiment of the present invention, the first cooling loop 810 is associated with the rack of modular units rather than each individual modular unit 250. Each modular unit possesses an internal network of channels and capillaries 840 that are in thermal contact with the electronic components contained within the modular unit. As described in previous embodiments, heat produced by the electronic components is transferred to a coolant associated with the first cooling loop 810.

FIG. 8 shows the first cooling loop 810 extracting heat from the electronic components associated with three modular units installed in the rack. As opposed to the first cooling loop 810 being entirely contained within each modular unit as previously described, the first cooling loop is associated with each modular unit in the rack via a series of quick connect/disconnects. Each modular unit, upon installation into the rack, connects to the cooling loop 810 associated with that rack eliminating the need for each modular unit to have a pump and means to transfer heat to the second cooling loop 395. Rather, a centralized pump 830 associated with each rack circulates coolant to each of the installed modular units. Thus, the operation of the first cooling loop 810 is continuous and independent of the number of installed modular units.

As the coolant from the first cooling loop 810 circulates to the various modular units, it collects heat from various electronic components contained within. The first cooling loop 810 conveys the coolant to a heat exchanger assembly 720 which interfaces with the second cooling loop 395. The heat exchanger assembly 720 allows heat associated with the first cooling loop 810 to be transferred to the second cooling loop 395 via conduction. As previously described, the second cooling loop 395 carries the heat via coolant associated with the second cooling loop 395 outside of the data center 100 environment.

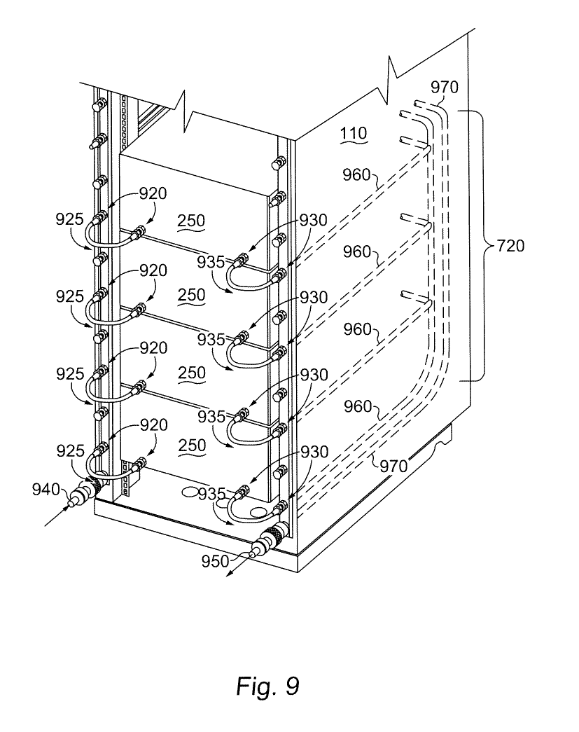

FIG. 9 shows a perspective view of a rack for housing modular components using a system for cooling of electronic components according to the embodiment of FIG. 7 while preserving the integrity of a data center cooling structure. Each modular unit 250 is coupled to the cooling system for the rack 110 via input connections 920 and an input conduit 925 as well as output connections 930 and an output conduit 935. The rack 110 is also coupled to the data center cooling system 100 via a system input connection 940 and a system output connection 950. Internal to the rack (not shown) is a pump for circulating coolant associated with the rack coolant system to each modular unit 250, and a heat exchanger assembly 720 for conveying the heat collected by the coolant of the rack cooling system to the coolant associated with the data center cooling system. Conduits within the rack 110 transport the coolant associated with rack coolant system 960 to the heat exchanger assembly. Likewise, conduits 970 fluidly couple the data center cooling system 100 to the heat exchanger assembly 720 wherein heat is conveyed from the rack coolant system to the data center cooling system 100. While the rack 110 becomes a permanent part of the data center cooling system 100, each modular unit 250 may be removed and replaced without affecting the integrity of the data center cooling system 100.

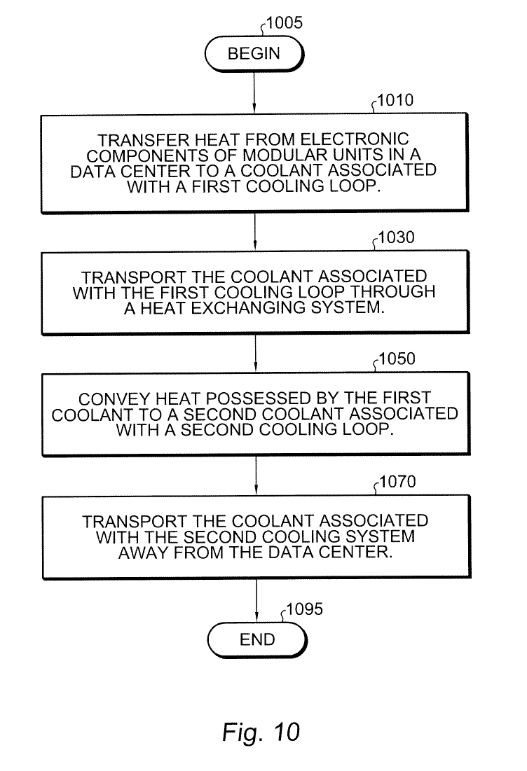

FIG. 10 is a flow diagram for a method for modular cooling of electronic components while preserving the integrity of a data center cooling structure according to one embodiment of the present invention. Heat associated with electronic components housed in each modular unit is transferred 1010 to a coolant associated with the first cooling loop. The coolant associated with this first cooling loop is thereafter transported 1030 to a heat exchanging system. The heat exchanging system conveys 1050 heat from the first cooling liquid associated with the first cooling loop to a second coolant associated with a second cooling loop. As described above, the heat exchanging system may comprise a conductive element or other configurations to convey the heat from one cooling loop to another. The second cooling loop thereafter transports 1070 the second coolant and heat associated therewith away from the data center environment.

The aforementioned embodiment of the present invention uses two or more liquid cooling loops to convey heat away from electronic components while maintaining the integrity of the cooling system associated with a data center. As will be appreciated by one skilled in the art, variations of the theme of the present invention are possible without departing from the intent and contemplated scope of the invention.

Particularly, it is recognized that the teachings of the foregoing disclosure will suggest other modifications to those persons skilled in the relevant art. Such modifications may involve other features which are already known per se and which may be used instead of or in addition to features already described herein. Although claims have been formulated in this application to particular combinations of features, it should be understood that the scope of the disclosure herein also includes any novel feature or any novel combination of features disclosed either explicitly or implicitly or any generalization or modification thereof which would be apparent to persons skilled in the relevant art, whether or not such relates to the same invention as presently claimed in any claim and whether or not it mitigates any or all of the same technical problems as confronted by the present invention. The Applicant hereby reserves the right to formulate new claims to such features and/or combinations of such features during the prosecution of the present application or of any further application derived therefrom.

I claim:

1. A system for modular cooling of electronic components while preserving the integrity of a data center cooling structure, the system comprising:
a modular unit configured to house within the modular unit a plurality of electronic components wherein the modular unit is mountable in a rack via a thermally conductive element;
a first liquid cooling loop configured to be in thermal contact with the plurality of electronic components within the modular unit and in thermal communication with a first portion of the thermally conductive element; and
a second liquid cooling loop in thermal communication with a second portion of the thermally conductive element wherein upon mounting the modular unit in the rack the first portion of the thermally conductive element is in physical and thermal contact with the second portion of the conductive element.

2. The system of claim 1, wherein the rack is an integrated portion of the second cooling loop.

3. The system of claim 1, wherein the rack is configured to house a plurality of modular units.

4. The system of claim 1, wherein the first liquid cooling loop is entirely contained within the modular unit.

5. The system of claim 1, wherein the first liquid cooling loop is entirely contained within the rack separate from the second liquid cooling loop.

6. The system of claim 1, wherein the first portion of the thermally conductive element comprises two or more surfaces extending from the modular unit, and wherein the second portion of the thermally conductive element comprises two or more surfaces configured to receive the two or more surfaces of the first portion of the thermally conductive element.

7. The system of claim 6, wherein the thermally conductive element comprises a lever configured to drive together the two or more surfaces of the first portion of the conductive element and the two or more surfaces of the second portion of the conductive element so as to increase thermal contact between the two or more surfaces of the first portion of the conductive element and the two or more surfaces of the second portion of the conductive element.

8. The system of claim 1, wherein each portion of the thermally conductive elements are co-joined with a thermally conductive interface to minimize voids when joined.

9. The system of claim 1, wherein the first portion of the thermally conductive element comprises a first channel capable of receiving cooling liquid from the first cooling loop and a second channel capable of returning cooling liquid to the first cooling loop.

10. The system of claim 1, wherein the second portion of the thermally conductive element comprises a first channel capable of receiving cooling liquid from the second cooling loop and a second channel capable of returning cooling liquid to the second cooling loop.

11. A cooling system for modular electronic components, the system comprising:
at least one modular unit mountable into a rack wherein the at least one modular unit is configured to house within the at least one modular unit a plurality of electronic components;
a first cooling loop configured to be in thermal contact with the plurality of electronic components within each at least one modular unit and in thermal communication with a heat exchanger; and
a second cooling loop configured to be thermal communication with the heat exchanger wherein heat from the plurality of electronic component is transferred to the first cooling loop, and wherein heat from the first cooling loop is transferred to the second cooling loop via the heat exchanger.

12. The system of claim 11, wherein the first cooling loop comprises a first liquid contained in a first conduit configured to flow between each modular unit and the heat exchanger.

13. The system of claim 11, wherein the second cooling loop comprises a second liquid contained in a second conduit configured to flow between the heat exchanger and an evaporator configured to extract heat from the second liquid.

14. The system of claim 11, wherein the cooling loop comprises a modular conduit portion wholly contained within each at least one modular unit and a rack loop portion, and wherein each modular portion is in fluid communication with the rack portion.

15. The system of claim 14, wherein upon removal of any modular portion of the cooling loop, the rack portion of the cooling loop and remaining modular portions remain functional.

16. A method for removing heat from one or more modular units mounted in a rack, wherein each modular unit houses a plurality of electronic components, the method comprising:
transferring heat generated from the plurality of electronic components to a first liquid contained within a first cooling loop, wherein the first cooling loop is in thermal contact with the plurality of electronic components, and the first cooling loop and the plurality of electronic components are wholly within the one or more modular units;
flowing the first liquid through at least one channel of a first portion of at least one conductive element transferring heat from the first liquid to the first portion of the at least one conductive element, wherein the first portion of the conductive element is affixed to a longitudinal length of the one or more modular units, and wherein the first portion of the at least one conductive element comprises at least two surfaces extending laterally from the longitudinal length;
coupling the first portion of the at least one conductive element to a second portion of the at least one conductive element, wherein the second portion of the at least one conductive element is affixed to the rack, and wherein the second portion of the at least one conductive element comprises at least two surfaces extending laterally from the from the rack toward the first portion of the at least one conductive element so as to interlock with surfaces extending laterally from the longitudinal length of the one or more modular units; and wherein heat from the first portion of the at least one conductive element flows to the second portion of the at least one conductive element; and
flowing a second liquid contained within a second cooling loop through at least one channel of the second portion of the at least one conductive element, wherein the second liquid accepts heat from the second portion of the at least one conductive element, and wherein the second cooling loop conveys heat away from the rack.

17. The method of claim 16, wherein the second cooling loop is thermally coupled to a plurality of racks.

18. The method of claim 16, further comprising pressing the surfaces of the first portion together with surfaces of the second portion of the at least one conductive element so as to increase surface contact.

19. The method of claim 16, wherein the first liquid and the second liquid are maintained in separate loops and have separate fluid reservoirs.

20. The method of claim 16, wherein integrity of the second cooling loop is maintained when one or more modular units are removed or replaced.
